(19) United States
(12) Patent Application Publication
(10) Pub. No.: US 2005/0156584 A1
(43) Pub. Date: Jul. 21, 2005

(54) Ion sensitive field effect transistor (ISFET) sensor with improved gate configuration

(75) Inventor: Chang-dong Feng, Long Beach, CA (US)

Correspondence Address: WESTMAN CHAMPLIN & KELLY, P.A., SUITE 1400 - INTERNATIONAL CENTRE, 900 SECOND AVENUE SOUTH, MINNEAPOLIS, MN, 55402-3319, US

(73) Assignee: Rosemount Analytical Inc., Irvine, CA (US)

(21) Appl. No.: 11/038,740

(22) Filed: Jan. 20, 2005

Related U.S. Application Data
(60) Provisional application No. 60/538,059, filed on Jan. 21, 2004.

(51) Int. Cl. H01L 23/58

(52) U.S. Cl. 324/71.5; 204/419; 257/253

(57) ABSTRACT

An ion sensitive field effect transistor pH sensor is provided with an improved sensor gate configuration. Specifically, a tantalum oxide-sensing gate is disposed on top of an alumina layer. The tantalum oxide-sensing gate provides advantageous sensitivity, while the alumina barrier layer increases sensor longevity in situations where the sensor is exposed to caustic cleaning processes such as Clean In Place processes.

### CROSS REFERENCE TO RELATED APPLICATIONS

This application claims the priority of an earlier filed co-pending provisional application Ser. No. 60/538,059, filed Jan. 21, 2004, entitled MULTI-LAYERED GATE DIELECTRICS FOR PH ISFET SENSOR.

### BACKGROUND OF THE INVENTION

The present invention relates to an ion sensitive field effect transistor (ISFET) sensor for sensing ion activity of a sample solution and, more particularly, to an improved gate arrangement for such a sensor.

An ISFET is similar to a metal oxide semiconductor field effect transistor (MOSFET), but does not have a conductive gate terminal. Instead, an ion-sensitive membrane is placed over the gate or channel region and is exposed to a sample solution. The remainder of the ISFET device is encapsulated. The lead that would be attached to the gate terminal of a MOSFET is attached to a reference electrode. The reference electrode is separated from the ion-sensitive membrane by the solution. The ion-sensitive membrane modulates the gate charge, and thus the potential difference between the gate and the reference electrode, as a function of the ion concentration in the sample solution. One or more operating characteristics of the ISFET are then measured and used to calculate the ion concentration.

The use of ISFETs for sensing ions is known. For example, U.S. Pat. No. 5,833,824 assigned to Rosemount Analytical, Inc., the Assignee of the present invention, discloses such a sensor. One of the most promising markets for pH ISFET sensors in process control appears to be the food and beverage market because the traditional pH glass sensor is generally prohibited from the process. The food and beverage market requires such sensors to be able to be Cleaned In Place (CIP). The Clean In Place process for such sensors typically involves subjecting the sensors to a 2% sodium hydroxide (NaOH) solution at 85° C. for a period of approximately 30 minutes for each cleaning. This Clean In Place process attacks and deteriorates ISFET devices.

It is also known that different materials have different sensing characteristics when used as ion-sensing membranes of pH ISFETs. For example, U.S. Pat. No. 5,309,226 indicates a number of characteristics for materials such as silicon dioxide (SiO₂), silicon nitride (Si₃N₄), alumina (Al₂O₃), zirconia (ZrO₂), and tantalum oxide (Ta₂O₅).

While some materials may be more effective as ion-sensing membranes, other materials may be able to withstand Cleaning In Place (CIP) more effectively. However, in the past, the art has always had to sacrifice one feature or the other. The provision of an ion-sensitive field effect transistor sensor that did not involve any such sacrifices would represent a significant benefit to the art.

### SUMMARY

An ion sensitive field effect transistor pH sensor is provided with an improved sensor gate configuration. Specifically, a tantalum oxide-sensing layer is disposed on top of an alumina layer. The tantalum oxide-sensing gate provides advantageous sensitivity, while the alumina barrier layer increases sensor longevity in situations where the sensor is exposed to caustic cleaning processes such as Clean In Place processes.

### BRIEF DESCRIPTION OF THE DRAWINGS

FIG. 1 is a cross sectional view of a pH-ISFET sensor in accordance with the prior art.

FIGS. 2a-2c are cross sectional views of a prior art pH-ISFET sensor undergoing deterioration in response to exposure to sodium hydroxide (NaOH).

FIG. 3 is a cross sectional view of a pH-ISFET sensor in accordance with embodiments of the present invention.

FIG. 4 is a chart illustrating sensor output in millivolts in response to various pH levels for sensors having different sensing membrane materials.

### DETAILED DESCRIPTION

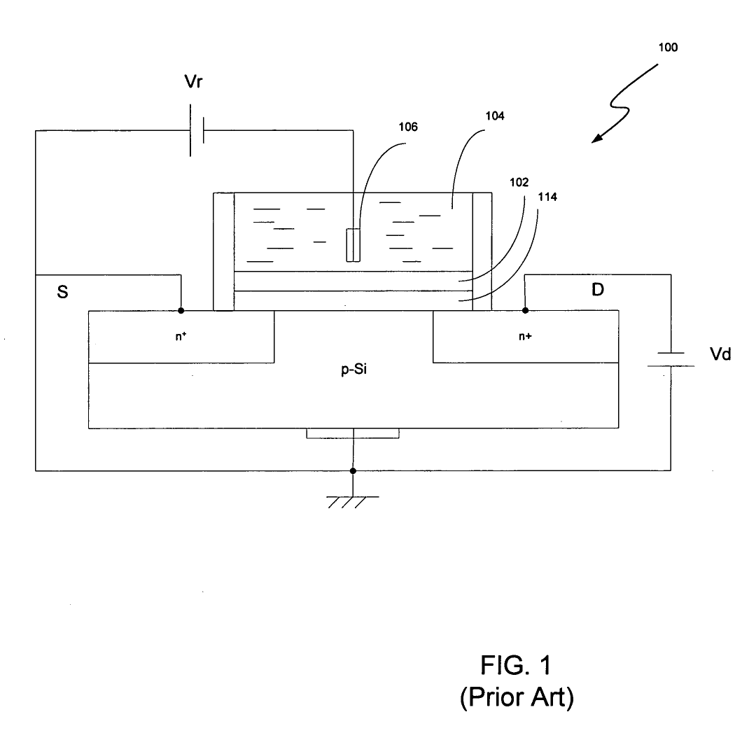

FIG. 1 is a cross sectional view of a pH ISFET sensor in accordance with the prior art. Prior art sensor 100 has a structure in which the metal gate region of a MOSFET is replaced by ion-sensing membrane 102 which reacts with hydrogen ions in sample solution 104 and provides operating characteristics that are similar to MOSFETs. Reference electrode 106 is disposed within sample solution 104 and maintains sample solution 104 at a substantially constant potential. When sensor 100 is exposed to sample solution 104, sensing membrane 102 reacts upon hydrogen ions in solution 104. This results in a change in the hydrogen ion concentration in membrane 102 and causes a difference in electrochemical potential between the membrane 102 and changes the chemical conductance of sensor 100. Accordingly, the change of concentration of the hydrogen ion in solution 104 can be detected since it is related to the drain current of sensor 100.

The selection of sensing gate materials used for pH ISEFTs is very important. The material itself contributes significantly to the ultimate sensitivity of the overall device. Popular materials include silicon nitride (Si₃N₄), alumina (Al₂O₃), and tantalum oxide (Ta₂O₅). Among these materials, it has been determined that the sensitivity of tantalum oxide as a sensing gate material is currently superior to all other sensing gate materials. This is because tantalum oxide shows virtually no drift of the sensor output. Conversely, other materials, such as alumina have been determined to suffer from a constant drift of the sensor output. However, extensive testing of pH ISFETs that employ tantalum oxide as a sensing membrane has revealed a significant limitation of that material for CIP applications. Specifically, pH ISFET sensors that employ tantalum oxide as a sensing membrane material deteriorate from exposure to the CIP process faster than most all other sensing membrane materials. For example, studies by the inventor have determined that pH ISFET sensor employing an alumina sensing membrane are able to withstand the CIP process for close to 30 hours, while pH ISFET sensors using a tantalum oxide-sensing membrane are only able to withstand the CIP process for approximately 10 hours. It is theorized that the shorter CIP life of tantalum-oxide based sensing membrane sensors is caused by the development of pinholes, or other porous passageways through the tantalum oxide-sensing gate.

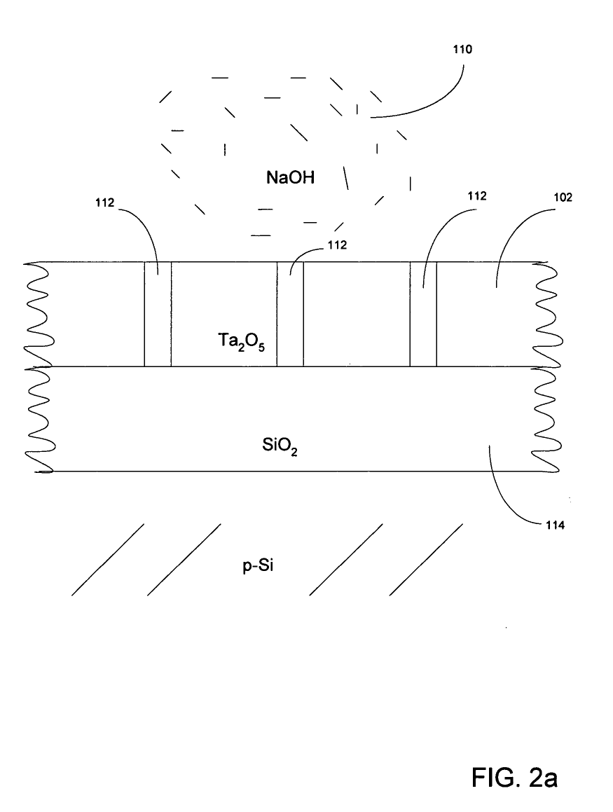

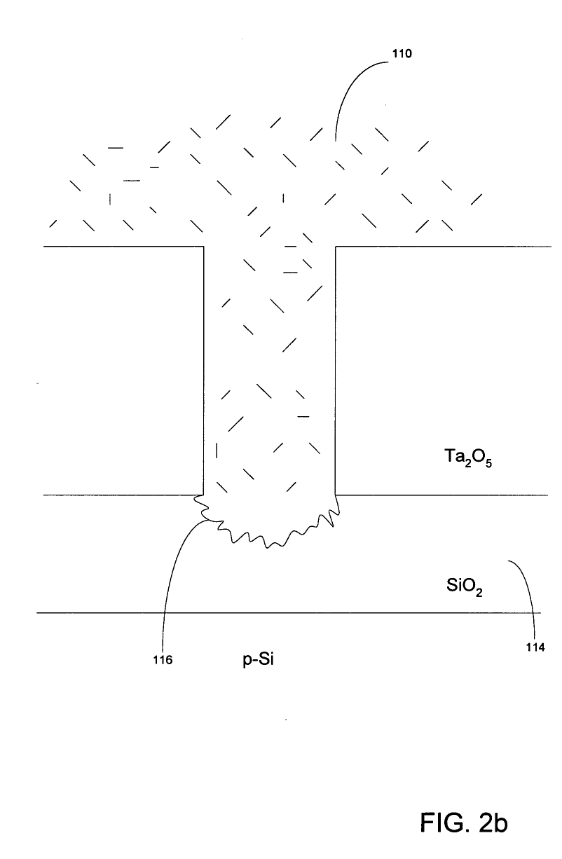

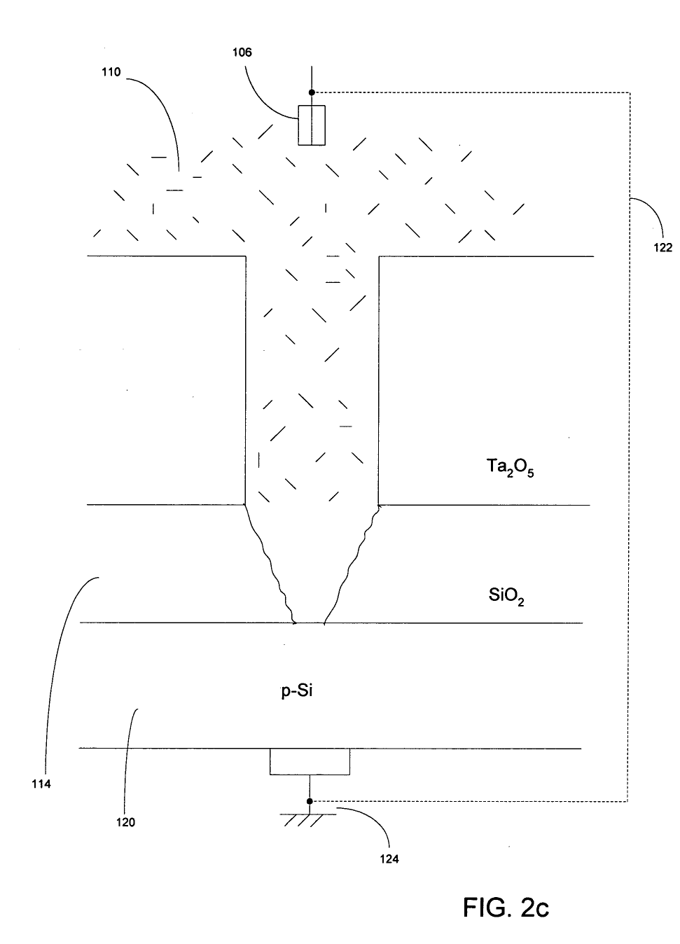

FIGS. 2a-2c are cross sectional views of a portion of a tantalum oxide based pH ISFET sensor illustrating this deterioration. In FIG. 2a, the sodium hydroxide cleaning solution 110 is shown above tantalum oxide-sensing gate 102. A plurality of pinholes 112 are illustrated in significantly enlarged form for purposes of this description. Each of pinholes or pores 112 allows the cleaning solution 110 to fluidically communicate with silicon oxide layer 114. As illustrated in FIG. 2b, solution 110 will begin to etch or otherwise dissolve the silicon dioxide of layer 114. FIG. 2b illustrates this process in operation at cavity 116. FIG. 2c illustrates cleaning solution 110 having completely eaten through layer 114 such that solution 110 is in communication with silicon layer 120. When this happens, a short circuit, illustrated in phantom at 122 is created between electrode 106 and ground 124. Experiments have indicated that the pinhole development through an alumina-sensing gate is a much slower process than the development of pinholes or porous passageways through a tantalum oxide-sensing gate. In order to realize the benefits of a tantalum oxide-sensing gate layer with the advantageous longevity characteristics of alumina, embodiments of the present invention provide a multi-layered sensing gate arrangement wherein tantalum oxide is exposed to the sensing solution, and an alumina sub-layer is interposed between the tantalum layer and the grown silicon oxide layer.

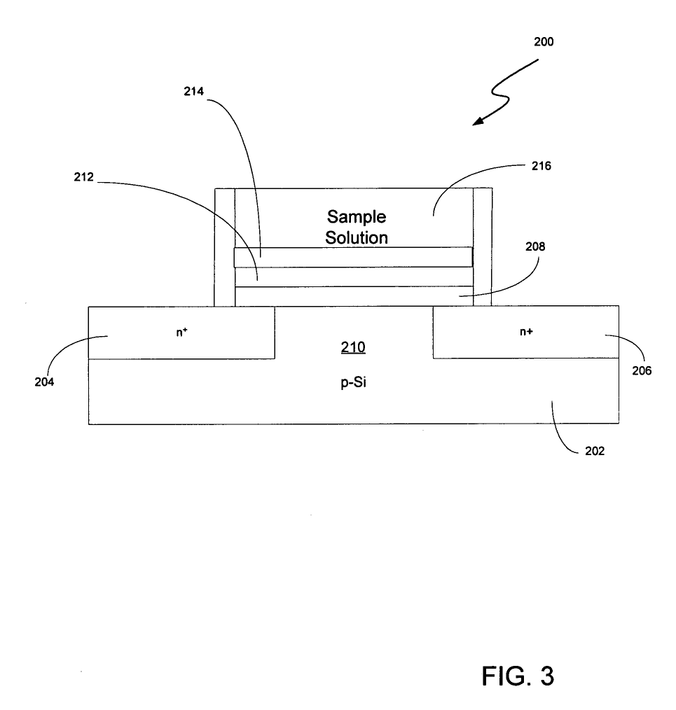

FIG. 3 is a cross sectional view of a pH ISFET sensor 200 in accordance with embodiments of the present invention. Sensor 200 includes a p-Si substrate 202 having n+regions 204 and 206. Although the description will focus upon an npn ISFET embodiment, it is expressly contemplated that other doping configurations, such as pnp, could also be used. A thermally grown silicon oxide layer 208 is disposed on top of region 210 of substrate 202 which layer 208 spans regions 204 and 206. An alumina barrier layer 212 is disposed on top of silicon oxide layer 208. Finally, tantalum oxide layer 214, preferably having a thickness between about 100 angstroms and about 5000 angstroms, is disposed on top of alumina layer 212 and is adapted for exposure to sample solution 216. Adapting layer 214 for exposure to a solution may include providing sidewalls to help cup the solution, or any other suitable configuration. Since pH ISFET 200 employs all semiconductor-based materials, standard semiconductor-processing techniques and methods can be used to manufacture the improved sensor in accordance with embodiment of the present invention. The arrangement of tantalum oxide as the sensing layer on top of alumina as a barrier layer provides the advantageous sensing characteristics of tantalum oxide while simultaneously providing the longevity characteristics of an alumina based sensor. It is believed that this sensor will be particularly advantageous for more accurately sensing hydrogen ions in applications that require Clean In Place processing, and that such sensor will do so for a lifetime similar to that of a sensor that used solely alumina as the sensing gate material.

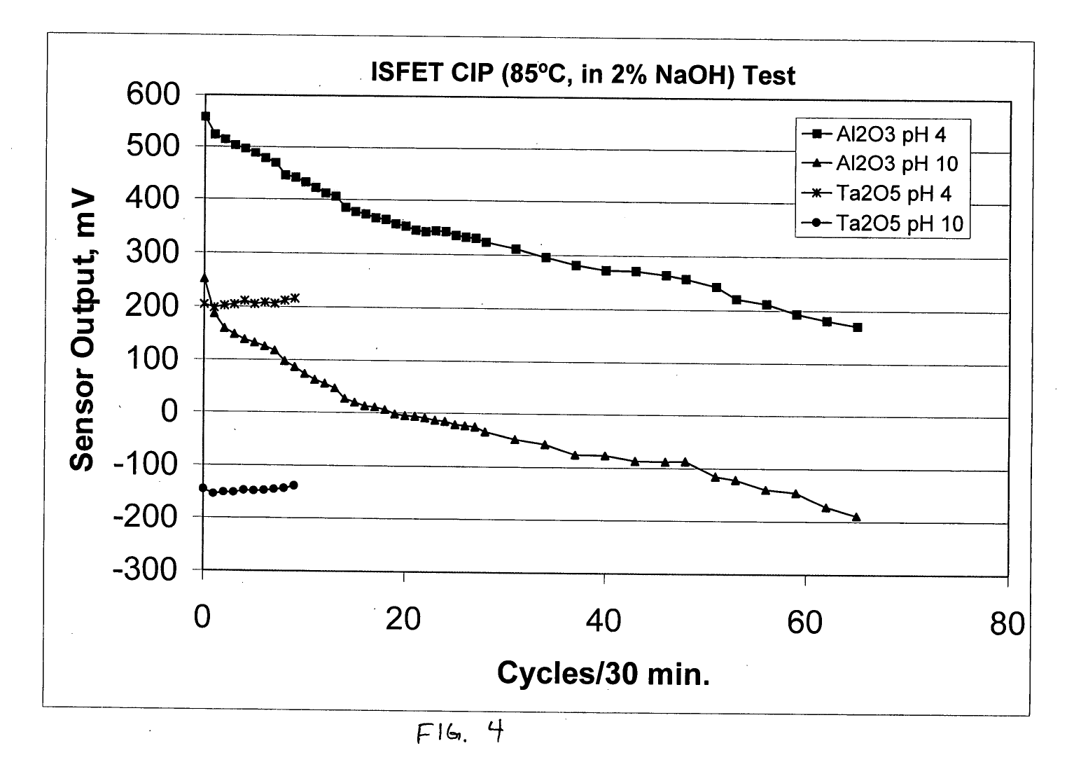

FIG. 4 is a chart of sensor output versus cycles for two different types of pH-ISFET sensors. FIG. 4 illustrates that a tantalum oxide-based pH sensor had relatively little drift, but was only able to withstand approximately 10 cycles of Clean In Place exposure (2% sodium hydroxide at 85° C.). However, a pH-sensing ISFET sensor having an alumina sensing gate was able to withstand approximately 65 cycles, but experienced significant drift. Thus, it is believed that a sensor having the tantalum oxide-sensing gate disposed over an alumina barrier layer will provide the sensor drift characteristics exhibited in FIG. 4 for the tantalum oxide sensor, but will last approximately 65 cycles or more.

Although the present invention has been described with reference to preferred embodiments, workers skilled in the art will recognize that changes may be made in form and detail without departing from the spirit and scope of the invention.

1. An ion sensitive field effect transistor (ISFET) comprising:
a substrate having a sensing region;
a layer of silicon oxide (SiO₂) disposed over the sensing region of the substrate;
a barrier layer of alumina disposed over the layer of silicon oxide;
a tantalum oxide (Ta₂O₅) sensing membrane disposed over the barrier layer, and being configured for exposure to a solution.

2. The ISFET of claim 1, wherein the tantalum oxide sensing membrane has a thickness between about 100 and 5000 angstroms.

3. The ISFET of claim 1, wherein the silicon oxide layer is thermally grown on the substrate.

4. The ISFET of claim 1, wherein the ISFET is an npn ISFET.

5. The ISFET of claim 1, wherein the ISFET is a pnp ISFET.

6. A method of sensing ions with an ISFET, the method comprising:
contacting a tantalum oxide sensing membrane of the ISFET with a sample solution;
allowing ions in the sample solution to interact electrically with the sensing layer;
providing an alumina barrier layer proximate the sensing layer; and
measuring a drain current of the ISFET.
